(19) United States
(12) Patent Application Publication
(10) Pub. No.: US 2025/0079407 A1
(43) Pub. Date: Mar. 6, 2025

(54) POWER ELECTRONICS MODULE AND ASSEMBLY METHOD

(71) Applicant: ZF Friedrichshafen AG, Friedrichshafen (DE)

(72) Inventors: Ake Ewald, Hamburg (DE); Stefan Hain, Speichersdorf (DE)

(73) Assignee: ZF Friedrichshafen AG, Friedrichshafen (DE)

(21) Appl. No.: 18/824,574

(22) Filed: Sep. 4, 2024

(30) Foreign Application Priority Data
Sep. 4, 2023 (DE) 10 2023 208 490.2

(51) Int. Cl. H01L 25/07; H01L 23/00; H01L 23/373; H01L 23/538; H01L 25/00

(52) U.S. Cl. CPC H01L 25/072; H01L 23/3735; H01L 23/5386; H01L 24/32; H01L 25/50; H01L 2224/32225

(57) ABSTRACT

A power electronics module includes first and second printed circuit boards, each having an upper and lower layer made of an electrically conductive material and a middle layer made of a non-conductive material, a high-side assembly having a power semiconductor forming a high-side switch, and a low-side assembly having a power semiconductor forming a low-side switch, wherein the first printed circuit board is placed opposite the second printed circuit board such that the upper layers face one another, wherein the upper layer of the first printed circuit board forms an AC-phase connection, and wherein the upper layer of the second printed circuit board forms a DC− and DC+ connection, and AC connections of the power semiconductors point toward and contact the upper layer of the first printed circuit board, and the DC connections for the power semiconductors point toward and contact the upper layer of the second printed circuit board.

### CROSS-REFERENCE TO RELATED APPLICATION

This application claims priority to German Application No. DE 10 2023 208 490.2, filed on Sep. 4, 2023, the entirety of which is hereby fully incorporated by reference herein.

### FIELD

The present disclosure relates to electric mobility, in particular the electronics module.

### BACKGROUND

The use of electronics modules in motor vehicles, specifically power electronics modules, has increased substantially over the last few decades. This is due partly to the need to improve fuel consumption and vehicle performance, and partly to the advances in semiconductor technology. To be able to provide the electricity, a number of electronic components are needed, with which bridge circuits (i.e. half-bridges) are obtained, e.g. semiconductor switches, also referred to as power semiconductors. Power semiconductors can be incorporated in complete power electronics modules (also referred to as power modules), or form discrete components. Power electronics modules contain a printed circuit board populated with power semiconductors that are connected to one another on the printed circuit board for conducting electricity and control signals.

The power semiconductors in the electronics module must be actively cooled in order to reduce switching and power losses. To be able to connect the power semiconductors easily, they are placed in a two-dimensional plane, with the phase pickups (AC) between the power semiconductors. This makes them easy to produce in a plane, resulting, however, in a less than optimal commutation cell.

To increase the cooling effect, various concepts have been proposed in which cooling is also obtained through the upper surfaces of the power semiconductors 3.1, 3.2 with heat sinks 5, 6, as schematically indicated in FIG. 1. The typical two-dimensional layout of the chip assembly is maintained, and the upper structure of the power semiconductor 3.1, 3.2 is connected thermally thereto, resulting in improved cooling. A load connection between the source S forming the high-side power semiconductor 3.1 and the drain D forming the low-side power semiconductor 3.2 must be obtained if MOSFETs are used. This connection can be formed by wire bonds, as indicated in FIG. 1 by the curved lines. This requires space on the power semiconductor 3.1 forming the high side (limiting the upward thermal conductance) and the part of the printed circuit board, normally formed by a DBC printed circuit board 1, forming the AC phase (AC pickup). Alternatively, part of the load path can be formed in the upper DBC printed circuit board 2, which requires additional components, however, to connect to the lower DBC printed circuit board 1. One example of an electronic module of this type, cooled on both sides, is disclosed in U.S. Pat. No. 10,211,133 B2.

In addition to optimizing the thermal path, an optimization of the electrical properties within the power electronics module is of major importance. The normal approach, of cooling the electronics module from two sides, does not result in this electric optimization.

### SUMMARY

An object of the present disclosure is to therefore create a power electronics module with which improved cooling is obtained, in particular through cooling from both sides of the power semiconductor, resulting in electrical optimization.

This problem is solved by the features of the present disclosure. Advantageous embodiments are also the subject matter of the present disclosure.

A power electronics module is proposed that contains a first printed circuit board with a upper layer made of an electrically conductive material, a middle layer made of a non-conductive material, and a lower layer made of an electrically conductive material, and a second printed circuit board with an upper layer made of an electrically conductive material, a middle layer made of a non-conductive material, and a lower layer made of an electrically conductive material, and a high-side assembly containing at least one power semiconductor forming a high-side switch, and a low-side assembly containing at least one power semiconductor forming a low-side switch, in which the first and second printed circuit boards are place one on top of the other such that the upper layers face one another, in which the upper layer of the first printed circuit board forms an AC phase connection, and the upper layer of the second printed circuit board forms a negative DC and positive DC connection, and the power semiconductor forming the high-side switch and the power semiconductor forming the low-side switch are placed such that their AC connections point toward the upper layer of the first printed circuit board and thus come in contact therewith, and the DC connections on the power semiconductors point toward the upper layer of the second printed circuit board, and thus come in contact therewith.

In one embodiment, there is one spacer for each power semiconductor, with the spacer for the power semiconductor forming the high-side switch placed between the upper layer of the first printed circuit board and the power semiconductor and in electrical and thermal contact with the first printed circuit board and the power semiconductor, and the spacer for the power semiconductor forming the low-side switch placed between the upper layer of the second printed circuit board and the power semiconductor and in electric and thermal contact with the first printed circuit board and power semiconductor, or the spacer for the power semiconductor forming the low-side switch placed between the upper layer of the first printed circuit board and the power semiconductor, and in electric and thermal contact with the second printed circuit board and the power semiconductor.

In one embodiment, the power electronics module also contains at least one signal/control rail for each power semiconductor, and each power semiconductor has at least one signal/control connection on the side that comes in contact with one of the DC connections, which is in contact with the dedicated signal/control rail through connecting elements.

In one embodiment, the upper layer of the second printed circuit board is structured such that a first part forms a contact region for an AC rail, and there is an AC spacer on this contact region, which is placed such that it forms an AC connector to the upper layer of the first printed circuit board.

In one embodiment, the upper layer of the second printed circuit board is structured such that a second part thereof forms a signal/control connection, and there is a spacer on the signal/control connection that is placed such that is forms a connector to a signal/control connection on the upper layer of the first printed circuit board.

In one embodiment, the upper layer of the first printed circuit board covers the entire power semiconductor.

In one embodiment, the lower layer of each printed circuit board has a dedicated heat sink to which it is thermally coupled.

In one embodiment, the printed circuit boards are DBC printed circuit boards, AMB printed circuit boards, or IMS printed circuit boards.

An assembly method for the power semiconductor module is also provided, in which the power semiconductor is placed on the dedicated printed circuit board in a first step, and the load connections and signal/control connections are connected to their dedicated rails by one or two lead frames in another, third step, and the printed circuit boards are united in a fourth step, in that both upper layers of the printed circuit boards with the power semiconductors thereon are placed one on top of the other, and connected at points intended for this.

In one embodiment, the power semiconductor module is encased in a casting compound in a fifth step, and the lead frame(s) are removed in a sixth step, such that only the rails and the contact elements connected to the signal/control connections protrude from the casting compound.

In one embodiment, spacers are placed on the power semiconductors and/or the upper layers of the printed circuit boards in a second step, between the first and third steps, or following the third step.

An electric drive for a vehicle is also provided, which has a power electronics component that contains at least the power electronics module described above.

Other features and advantages of the present disclosure can be derived from the following description of exemplary embodiments in reference to the drawings illustrating details of the present disclosure, and the claims. The individual features can be obtained in and of themselves, or in various arbitrary combinations forming variations of the present disclosure.

Preferred embodiments of the present disclosure shall be explained in greater detail below in reference to the drawings.

### BRIEF DESCRIPTION OF THE DRAWINGS

FIG. 1 shows a sectional view of the fundamental structure of a power electronics module with cooling on two sides according to the prior art.

FIG. 2 shows a sectional view of the fundamental structure of a power electronics module with cooling on two sides according to one embodiment of the present disclosure.

FIG. 3 shows a sectional view of the fundamental structure of a power electronics module with cooling on two sides according to an alternative embodiment of the present disclosure.

FIG. 4 shows an illustration of the fundamental structure of a power electronics module with cooling on two sides according to one embodiment of the present disclosure.

FIG. 5 shows an illustration of the fundamental structure of an upper printed circuit board with a lead frame according to one embodiment of the present disclosure.

FIG. 6 shows an illustration of the fundamental structure of an upper printed circuit board without a lead frame according to one embodiment of the present disclosure.

FIG. 7 shows an illustration of the fundamental structure of a lower printed circuit board with a lead frame according to one embodiment of the present disclosure.

FIG. 8 shows an illustration of the fundamental structure of a lower printed circuit board without a lead frame according to one embodiment of the present disclosure.

FIG. 9 shows an illustration of the fundamental structure of a power electronics module with cooling on two sides, with lead frames according to one embodiment of the present disclosure.

FIG. 10 shows an illustration of the fundamental structure of an upper printed circuit board according to another embodiment of the present disclosure.

FIG. 11 shows an illustration of the fundamental structure of a lower printed circuit board without lead frames and with (AC/DC/signal/control) rails according to the other embodiment of the present disclosure.

FIG. 12 shows an illustration of the fundamental structure of a lower printed circuit board with a lead frame according to the other embodiment of the present disclosure.

FIG. 13 shows an illustration of the fundamental structure of a power electronics module with cooling on both sides with a lead frame according to the other embodiment of the present disclosure.

FIG. 14 shows an illustration of the fundamental structure of a power electronics module with cooling on both sides without lead frames according to the other embodiment of the present disclosure.

FIG. 15 shows a flow chart for the method for producing a power electronics module with cooling on both sides according to one embodiment of the present disclosure.

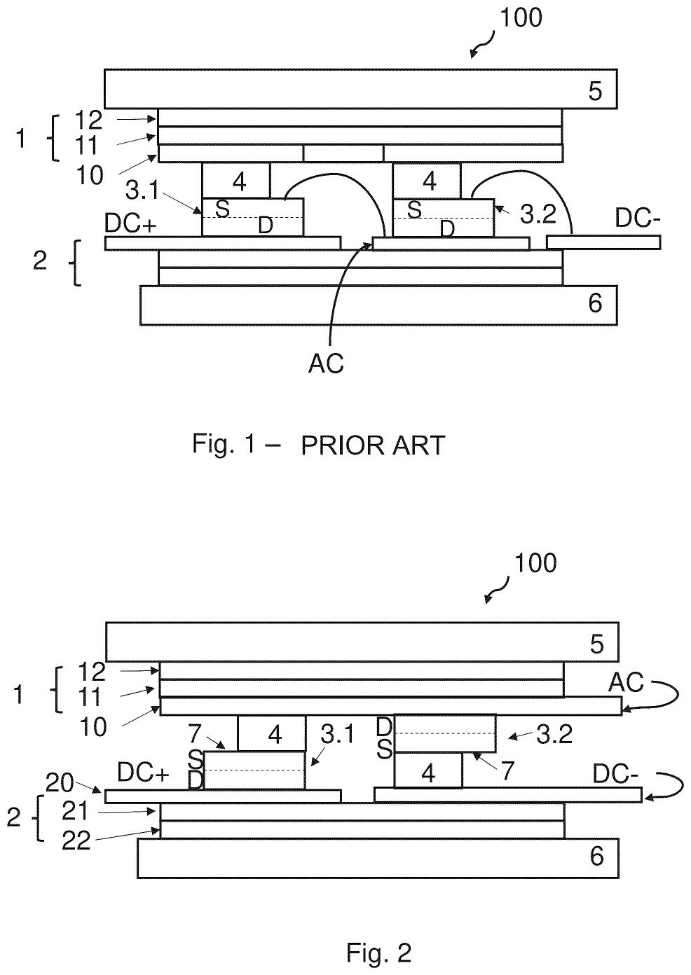

### DETAILED DESCRIPTION

Identical elements or functions have the same reference symbols in the following description of the drawings.

The present disclosure results in a two-sided cooling of power electronics modules 100 for use with power electronics components, e.g. DC/AC inverters in the automotive industry in which the electrical commutation is improved, the thermal connection is optimized, and the power electronics module 100 has a simple structure.

A power electronics module 100 normally provides one phase (with an AC phase pickup) of an inverter. To obtain a three-phase inverter, three of these power electronics modules 100 are connected together. There are numerous different methods for doing this, which do not need to be described here. Because the same types of power electronics modules 100 are normally connected together, only one power electronics module 100 shall be described.

The power electronics module 100 cooled on two sides described below in reference to FIGS. 2 to 14 has two printed circuit boards 1, 2, each containing at least three layers, of which the upper layers 10, 20 are made of electrically conductive material, the middle layers 11, 21 are made of non-conductive material, e.g. ceramic, and the lower layers 12, 22 are made of electrically conductive material. One such printed circuit board is a DBC printed circuit board. DBC stands for direct bonded copper, which can also be referred to as DCB (direct copper bonded). An AMB (active metal brazing) or IMS (insulated metal substrate) printed circuit board can also be used, as long as it contains at least three layers.

The upper layer 10 of the first printed circuit board 1 in the present disclosure forms an AC contact. The upper layer 20 of the second printed circuit board 2 forms a DC-phase contact (DC− and DC+). The upper layers 10, 20 of the two printed circuit boards 1, 2 face one another in the assembled state.

The electronics module 100 also has at least one half-bridge, i.e. at least one power semiconductor 3.1 that forms a high-side switch in a high-side assembly, referred to below as a high-side switch 3.1, and a power semiconductor 3.2 that forms a low-side switch in a low-side assembly, referred to below as the low-side switch 3.2.

The low-side assembly, i.e. the low-side switch(es) 3.2 are placed on the upper layer 10 of the first printed circuit board 1 such that their AC-phase contacts (with MOSFETs the drain D, with IGBTs the collector corresponding to the drain) are in electrical contact with the upper layer 10. The DC contact (with MOSFETs the source, with IGBTs the emitter, corresponding to the source) therefore faces toward the upper layer 20 of the second printed circuit board 2.

In a preferred embodiment, there is a spacer on the DC contact(S) for the low-side switch 3.2, which is therefore in electrical and thermal contact with both the DC contact(S) and the upper layer 20 of the second printed circuit board 2.

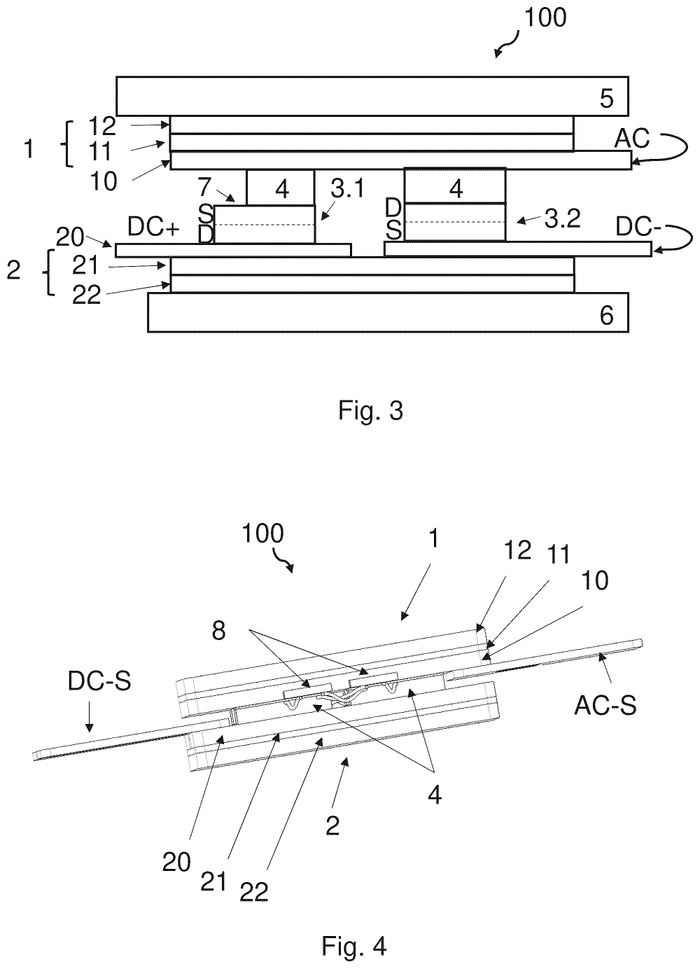

In another embodiment, (shown in FIG. 3), the DC contact (with MOSFETs the source S, with IGBTs the emitter) in the low-side assembly is in direct contact with the upper layer 20 of the second printed circuit board, and the spacer 4 is placed on the AC-phase contact (with MOSFETs the drain D, with IGBTs the collector), and in contact with the upper layer 10 of the first printed circuit board 1. This embodiment is less advantageous, because it is more difficult to produce a contact therewith to the signal/control connections 7 described below.

The high-side assembly, i.e. the high-side switch(es) 3.1 are placed on the upper layer 20 of the second printed circuit board 2 such that their DC contacts (with MOSFETs the drain D, with IGBTs the collector) are in electrical contact with the upper layer 20. Their AC-phase contacts (with MOSFETs the source S, with IGBTs the emitter) face toward the upper layer 10 of the first printed circuit board 1. There is a spacer 4 on the AC-phase contact of the high-side switch 3.1 (S) in one embodiment, which is in electrical and thermal contact with the AC-phase contact(S) and the upper layer 10 of the first printed circuit board.

In these embodiments, the low-side assembly is therefore on the first printed circuit board 1 and the high-side assembly is on the second printed circuit board 2 prior to assembly.

The spacers 4 in both phases (high-side and low-side) are made of an electrically and thermally conductive material such as copper. The high-side switches 3.1 and low-side switches 3.2 are normally the same size, and the spacers 4 are normally the same height, such that the two printed circuit boards 1 and 2 can be connected to one another with as little tolerance as possible. Tolerances can still be compensated for when connecting the two printed circuit boards 1, 2, e.g. with solder.

Signal/control connections 7 are placed on the side of the AC-phase contacts for each power semiconductor 3.1, 3.2, such that the entire surface of the power semiconductor 3.1, 3.2 is not occupied by an AC-phase contact (load connection for AC). For this reason, the spacers 4 are designed such that they do not occupy the entire surface area of the respective power semiconductors 3.1, 3.2, leaving some area free, where instead of a load connection, there are signal/control connections 7. These signal/control connections 7 can form a gate connection or Kelvin-source connection. This leaves space at the level of the spacer 4 for obtaining contact to the signal/control connections 7 with contact elements, e.g. wire bonds. There can also be an intermediate cooling element (not shown) there, with which supplementary heat dissipation (heat dispersion) is obtained.

The signal/control connections 7 can be part of the printed circuit boards 1, 2, or external connections, depending on the assembly process, as described below in reference to assembly/production method.

The printed circuit boards 1, 2 function not only as electrical contacts, but also as thermal conductors with which heat is conducted to a heat sink 5, 6 on the lower layers 12, 22, thus cooling the power semiconductors 3.1 and 3.2.

The low-side switch 3.2 is rotated 180° (horizontally) in relation to the high-side switch 3.1 in the present disclosure, such that the AC connections on both power semiconductors 3.1 and 3.2 point in the same direction, i.e. toward the upper layer 10 of the first printed circuit board 1, and are therefore in electrical and thermal contact therewith (potentially through spacers 4, depending on the embodiment). The DC connections on both power semiconductors 3.1 and 3.2 also point in the same direction, i.e. toward the upper layer 20 of the second printed circuit board 2, and are thus in electrical and thermal contact therewith (potentially through spacers 4, depending on the embodiment). This results in a better commutation cell than in the prior art due to the three-dimensional arrangement of the DC+, phase AC, and DC−. This design also results in an optimized two-sided cooling of all of the power semiconductors 3.1, 3.2, because the connecting spacers 4 allow not only electricity, but also heat to be conducted to the second printed circuit board 2.

The direct connection of the drain D (with MOSFETs) in the individual power semiconductors 3.1 and 3.2 to the upper layers 10, 20 of the printed circuit boards 1, 2 results in a simplified production of the power electronics module 100 compared to the prior art, because fewer connecting elements, e.g. wire bonds, are needed.

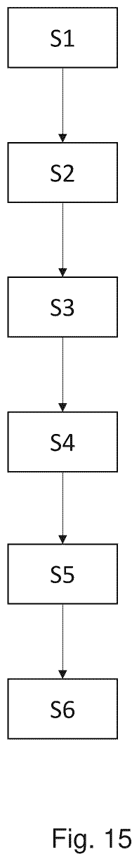

As indicated above, the signal/control connections 7, as well as the load connections (DC and AC) can be placed slightly differently, depending on the assembly/production process, as explained below. One version of the assembly/production process sequence is schematically illustrated in FIG. 15.

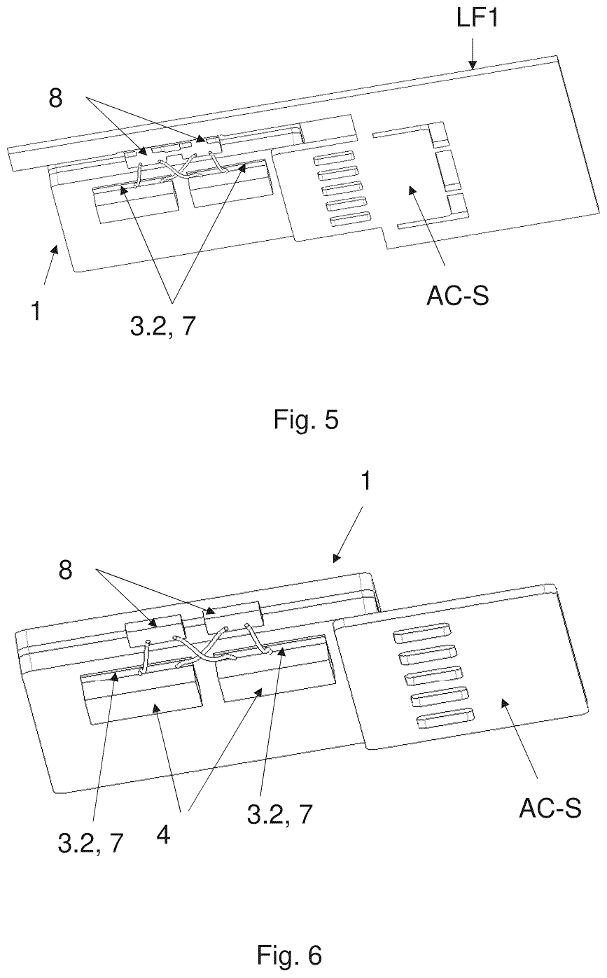

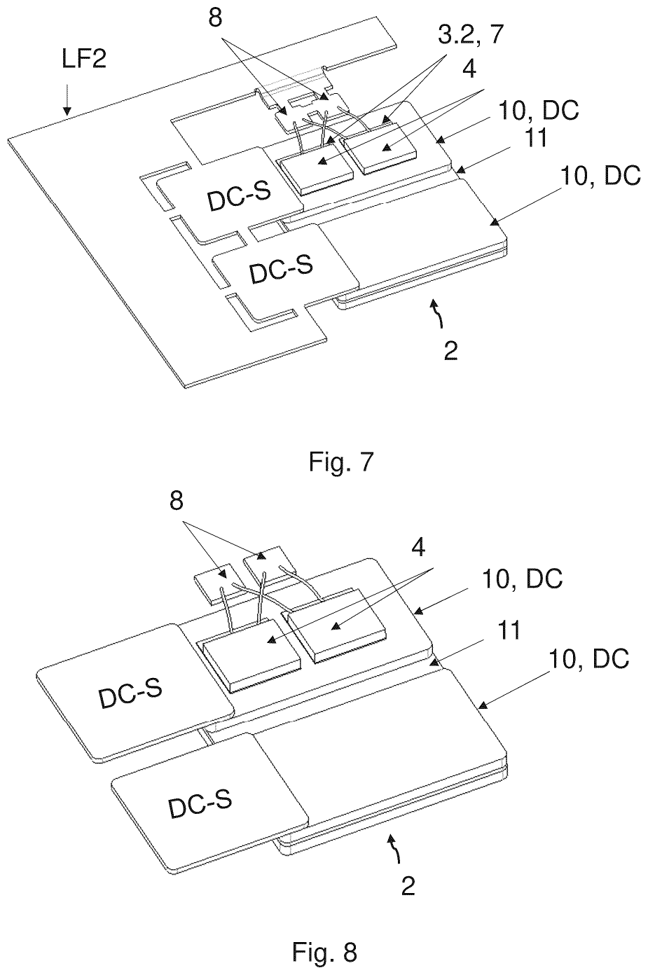

The power electronics module 100 shown in FIG. 4 is obtained in a first version of the assembly/production process. For this, the power semiconductors 3.1 and 3.2 are placed on their respective printed circuit boards 1, 2 (low-side on the first printed circuit board 1, and high-side on the second printed circuit board 2) in a first step S1. The power semiconductors 3.1 and 3.2 are advantageously sintered thereto (not soldered). The DC contact for the high-side switch 3.1 (drain D with MOSFETs), is therefore placed on the upper layer 20 of the second printed circuit board 2, and the AC-phase contact of the low-side switch 3.2 (drain D with MOSFETs) is placed on the upper layer 10 of the first printed circuit board 1, where they are thermally and electrically connected thereto. The upper layer 10 of the printed circuit board 1 remains entirely intact, i.e. remains unstructured, as can be readily seen in FIGS. 5 and 6. The upper layer 20 of the second printed circuit board 2 is structured, in order to insulate the DC+ and DC− from one another, as can be readily seen in FIGS. 7 and 8.

In a second step S2, the spacers 4 are placed on either the power semiconductors 3.1 and 3.2, or on the printed circuit boards 1, 2. The spacers 4 could also be placed in or after the third step S3, advantageously after contact has been obtained between the signal/control connections 7 and their dedicated rails (signal/control rails 8) using connecting elements. The sequence depends on the connecting elements that are used.

The load connections DC, AC and the signal/control connections 7 are connected to their dedicated rails (DC rail, DC-S, AC rail, AC-S, signal/control rail 8) in the third step S3. This takes place using lead frames LF1, LF2. Two lead frames LF1, LF2 are needed for the first version of the assembly/production process, resulting in two partial printed circuit boards 1, 2 with corresponding connections. As shown in FIG. 5, the first lead frame LF1 supports the AC rail AC-S, and signal/control rails 8 of the low-side switch 3.2, therefore belonging to the first printed circuit board 1. FIG. 6 shows the first printed circuit board 1 with the AC rail AC-S and the signal/control rails 8 after removing the unnecessary part of the lead frame LF1, in order to show the structure. As FIG. 7 shows, the second lead frame LF2 supports the DC rails DC-S for the DC+ and DC− and the signal/control rails 8 for the high-side switch 3.1, therefore belonging to the second printed circuit board 2. The first printed circuit board 2 with the DC rails DC-S and the signal/control rails 8 is shown in FIG. 8 after the unnecessary part of the lead frame LF2 has been removed in order to show the structure.

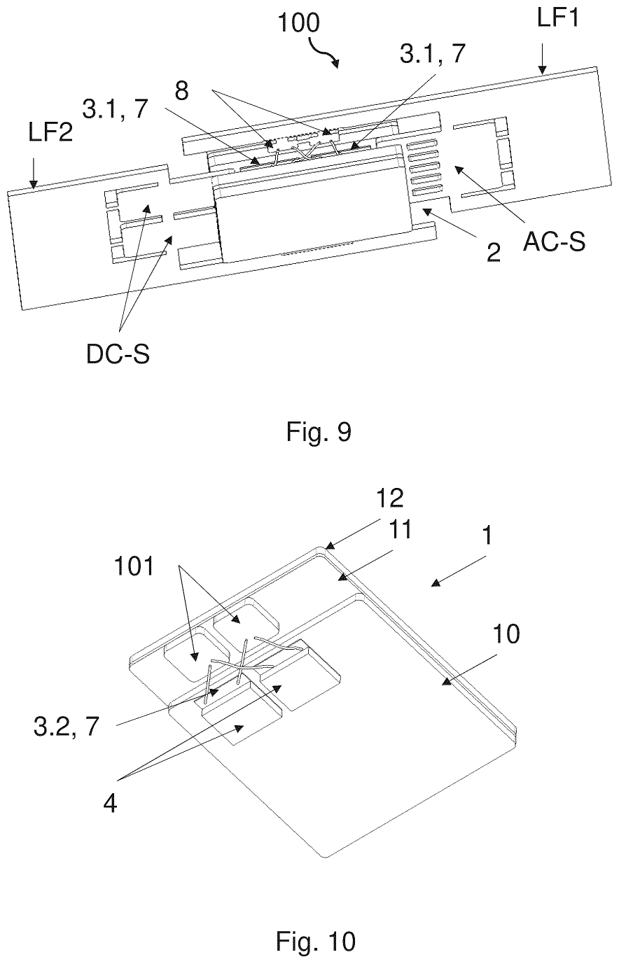

The two lead frames LF1, LF2 connected to their (populated) printed circuit boards 1, 2 are then united in the fourth step S4, in that the two upper layers 10, 20 of the printed circuit boards 1, 2 populated with the power semiconductors 3.1, 3.2 and spacers 4, are then placed on one another, and connected at the points provided for this, e.g. through sintering. These points are either the (free) sides of the spacers 4 (in the preferred embodiment shown in FIG. 2), lying opposite the power semiconductors 3.1, 3.2, or a (free) side of the spacer 4 lying opposite the power semiconductor 3.1 and the DC contact for the power semiconductor 3.2 (in the preferred embodiment shown in FIG. 3). A diagonal perspective of the united printed circuit boards 1, 2 with the lead frames LF1, LF2 is shown in FIG. 9. The power semiconductor module 100 obtained after removing the unnecessary parts of the lead frames LF1, LF2 (with the load rails DC-S, AC-S and the signal/control rails 8 pointing outward) is shown from a diagonal perspective in FIG. 4.

The power electronics module 100 is encased in a casting compound (not shown) in the fifth step S5, to protect it from environmental effects. This casting compound also holds the signal/control rails 8 in place, because they would otherwise hang freely from the connections (e.g. wire bonds) after removing the lead frames LF1, LF2. The lead frames LF1, LF2 are then removed in the last step S6. The casting compound encases the power electronics module 100 such that only parts of the load rails DC-S, AC-S and the signal/control rails 8 protrude from the casting compound after the lead frames LF1, LF2 have been removed.

As FIG. 4 shows clearly, there is space between the DC rails DC-S and the first printed circuit board 1 and between the AC rails AC-S and the second printed circuit board 2 after they have been united, such that there is no contact there.

In a second version of the assembly/production process, the power electronics module 100 shown in FIG. 14 is obtained. In this case, the power semiconductors 3.1 and 3.2 are placed on the respective printed circuit boards 1, 2, advantageously with a sintering process, as in the first embodiment.

As FIG. 10 clearly shows, the upper layer 10 of the upper printed circuit board 1 remains intact where the power semiconductors 3.1, 3.2 are located, but is structured at one edge to create islands 101 for the (electrical) contact of the signal/control connections 7 for the power semiconductor 3.2 on the upper layer 10 of the first printed circuit board 1 to the signal/control rails 8 provided in a later step. The spacers 4 are also placed on the power semiconductors 3.1, 3.2 or on the printed circuit boards 1, 2, as in the first embodiment.

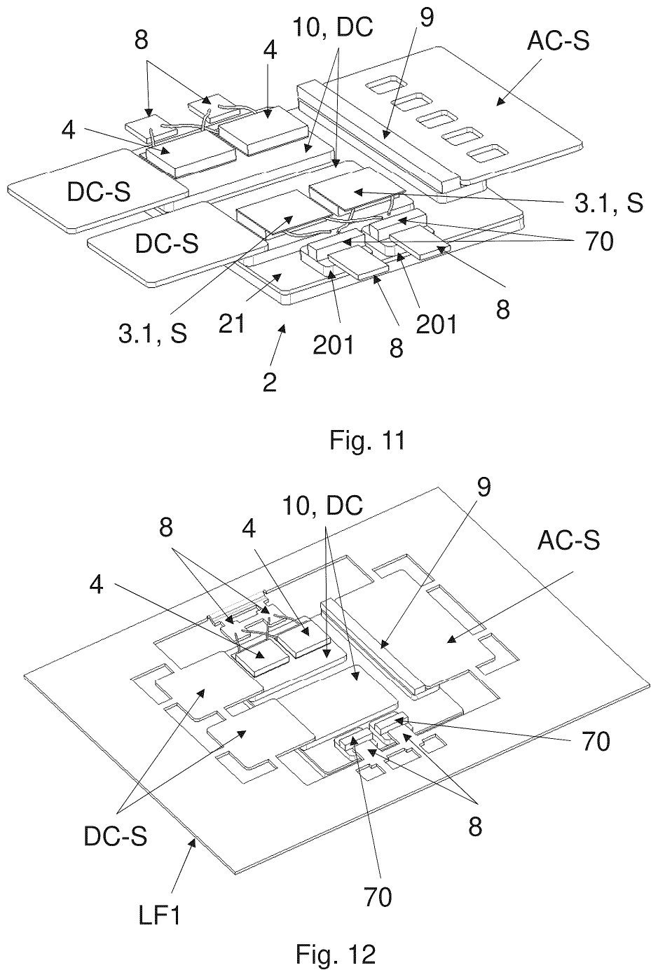

As can be clearly seen in FIG. 11, the upper layer 20 of the lower printed circuit board 2 is structured so that the load connections (DC and AC) and all signal/control connections 7 can be obtained.

In this embodiment, additional spacers 4 are placed on the upper layer 20 of the lower printed circuit board 2, where the AC-phase pickup AC (island forming part of the upper layer 20, as can be clearly seen in FIG. 11) and the signal/control connections 7 are located.

All of the spacers 4 on the printed circuit boards 1, 2 could also be first placed after the signal/control connections 7 are in contact with their dedicated rails (signal/control rails 8). The sequence depends on the connecting elements that are used.

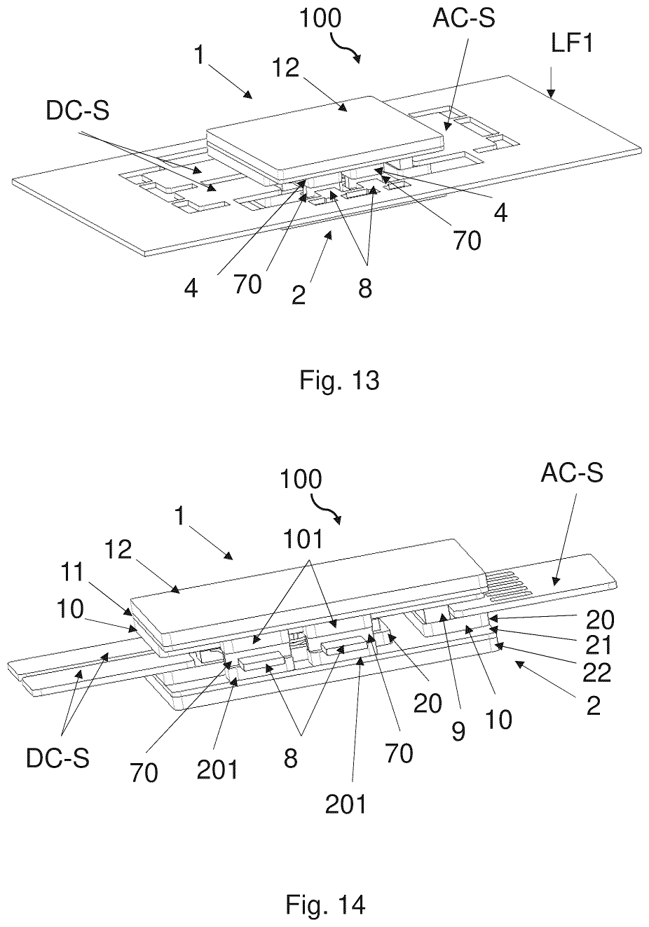

Because of the spacers 4 on the lower printed circuit board 2, only one lead frame LF1 is need in this assembly/production process, because all load rails (DC-S and AC-S) and all signal/control rails 8 are connected on the lower printed circuit board 2, as can be clearly seen in FIG. 12. FIG. 12 shows the lower printed circuit board 2 with the lead frame LF1 placed thereon, and FIG. 11 shows the printed circuit board 2 after the lead frame LF1 has been removed, i.e. with load rails (DC-S and AC-S) and all of the signal/control rails 8, but without the upper printed circuit board 1. FIG. 13 shows the united printed circuit boards 1, 2, which face toward each other with their upper layers 10, 20 and the power semiconductors 3.1, 3.2 placed thereon, as in all embodiments, with the lead frame LF1 still in place. FIG. 14 shows the united printed circuit boards 1, 2 without the lead frame LF1. As in the embodiment above, the casting compound encasing the power electronics module 100 is not shown, from which only parts of the load rails DC-S, AC-S and the signal/control rails 8 protrude.

For the AC rails AC-S and the signal/control rails 8 to be able to come in contact with the upper printed circuit board 1, spacers 70 are placed on the islands 201 (part of the upper layer 20) on the lower printed circuit board, on which the signal/control rails 8 are placed. There is also an AC spacer 9 where the AC contact to the AC rails AC-S (upper layer 20) is obtained. These spacers 70, 9 are made of an electrically and thermally conductive material such as copper, and form a contact (in particular an electrical contact) between the components on the first and second printed circuit boards 1, 2. They therefore form connecting elements. The spacers 4 (for the power semiconductors 3.1 and 3.2) are advantageously made of the same material as the spacers 70, 9.

The spacers 70, 9 can be placed on the printed circuit boards 1, 2 in a separate process step, or at the same time as other components, e.g. with the spacers 4.

Only one lead frame LF1 is necessary if the additional spacers 70, 9 are placed on the lower printed circuit board 2 (on the upper layer 20 thereof). The AC phase AC and the signal/control contacts 7 on the first printed circuit board 1 can be contacted electrically (and thermally) through the spacers 70, 9, in that the two printed circuit boards 1, 2 are united, as shown in FIGS. 13 and 14. As FIG. 14 clearly shows, there is space between the DC rails DC-S and the printed circuit board 1 after they are united, such that there is no contact there.

The connections (electrical/thermal contacts) are obtained through sintering in all of the embodiments. This means that soldering, with which different melting temperatures must be used, is unnecessary. Solder may still be used for a final connection, to compensate for tolerances. Material bonds can also be used, involving technologies such as “KlettWelding.”

There are heat sinks 5, 6 on the lower layers 12, 22 of the printed circuit boards 1, 2 in all of the embodiments, with which the power electronics module 100 is cooled.

A power electronics module 100 is used in the framework of the present disclosure for operating a motor vehicle powered by an electric motor (with a battery). The motor vehicle is specifically a utility vehicle such as a truck or bus, or a passenger automobile. The power electronics module contains a DC/AC inverter. It can also contain an AC/DC rectifier, a DC/DC converter, a transformer, and/or another electrical converter, or part of such a converter, or be part thereof. In particular, the power electronics module 100 is used to power an electric machine, e.g. an electric motor and/or generator. A DC/AC inverter is preferably used to generate a multi-phase alternating current from a direct current generated by a DC voltage from a power source such as a battery.

List of Reference Symbols

| | |
|---|---|
| 100 | power electronics module |
| 1 | first printed circuit board |
| 10 | upper layer |
| 101 | island/contact |
| 11 | middle layer |
| 12 | lower layer |
| 2 | second printed circuit board |
| 20 | upper layer |
| 201 | island/contact |
| 21 | middle layer |
| 22 | lower layer |
| 3.1 | high-side power semiconductor |
| 3. | low-side power semiconductor |
| S | source (emitter) |
| D | drain (collector) |
| 4 | spacer |
| 5, 6 | heat sink |
| 7 | signal/control connection (gate/Kelvin source connection) |
| 70 | spacer |
| 8 | signal/control rail |
| 9 | AC spacer AC rail |
| AC | AC connection |
| AC-S | AC rail |
| DC | DC connection (DC− or DC+) |
| DC-S | DC rail |
| LF1 | lead frame 1 |
| LF2 | lead frame 2 |

1. A power electronics module comprising:
a first printed circuit board comprising an upper layer made of an electrically conductive material, a middle layer made of a non-conductive material, and a lower layer made of an electrically conductive material;
a second printed circuit board comprising an upper layer made of an electrically conductive material, a middle layer made of a non-conductive material, and a lower layer made of an electrically conductive material;
a high-side assembly comprising at least one power semiconductor forming a high-side switch; and
a low-side assembly comprising at least one power semiconductor forming a low-side switch,
wherein the first printed circuit board is placed opposite the second printed circuit board such that the upper layers face one another,
wherein the upper layer of the first printed circuit board forms an AC-phase connection, and wherein the upper layer of the second printed circuit board is structured such that it forms a DC− and DC+ connection, and
wherein the power semiconductor forming the high-side switch and the power semiconductor forming the low-side switch are placed such that their AC connections point toward the upper layer of the first printed circuit board and come in contact therewith, and the DC connections for the power semiconductors point toward the upper layer of the second printed circuit board and come in contact therewith.

2. The power electronics module according to claim 1, comprising:
a spacer for each power semiconductor, and
wherein the spacer for the power semiconductor forming the high-side switch is placed between the upper layer of the first printed circuit board and the power semiconductor forming the high-side switch, and is in electrical and thermal contact with the first printed circuit board and the power semiconductor forming the high-side switch, and
wherein the spacer for the power semiconductor forming the low-side switch is placed between the upper layer of the second printed circuit board and the power semiconductor forming the low-side switch and in electrical and thermal contact with the first printed circuit board and the power semiconductor forming the low-side switch, or wherein the spacer for the power semiconductor forming the low-side switch is placed between the upper layer of the first printed circuit board and the power semiconductor forming the low-side switch and is in electrical and thermal contact with the second printed circuit board and the power semiconductor forming the low-side switch.

3. The power electronics module according to claim 1, comprising
at least one signal/control rail for each power semiconductor, wherein there is at least one signal/control connection on a side of each power semiconductor that comes in contact with one of the DC connections that is in contact with its dedicated signal/control rail through connecting elements.

4. The power electronics module according to claim 1,
wherein the upper layer of the second printed circuit board is structured such that a first part thereof forms a contact for an AC rail, and wherein an AC spacer is placed thereon such that it forms an AC connector to the upper layer of the first printed circuit board.

5. The power electronics module (100) according to claim 4,
wherein the upper layer of the second printed circuit board is structured such that a second part thereof forms a signal/control connection, and wherein there is a spacer on the signal/control connection that is placed such that it forms a connector to a signal/control connection on the upper layer of the first printed circuit board.

6. The power electronics module according to claim 1,
wherein the upper layer of the first printed circuit board completely covers the power semiconductors.

7. The power electronics module according to claim 1, comprising:
a heat sink on each of the lower layers of the first and second printed circuit boards and thermally coupled thereto.

8. The power electronics module according to claim 1,
wherein the first and second printed circuit boards are direct bonded copper (DBC) printed circuit boards, active metal brazing (AMB) printed circuit boards, or insulated metal substrate (IMS) printed circuit boards.

9. An electric drive for a vehicle, comprising:
the power electronics module according to claim 1.

10. An assembly method for a power electronics module comprising:
placing power semiconductors on dedicated printed circuit boards;
connecting load connections and signal/control connections to dedicated rails by one or two lead frames; and
uniting the printed circuit boards to one another in that upper layers of the printed circuit boards populated with the power semiconductors are placed one on top of the other and are connected at points.

11. The assembly method according to claim 10, comprising:
encasing the power electronics module in a casting compound; and
removing the one or two lead frames such that only the rails and contact elements connected to the signal/control connections still protrude from the casting compound.

12. The assembly method according to claim 10, comprising:
placing spacers on the power semiconductors and/or the upper layers of the printed circuit boards after placing the power semiconductors on their dedicated printed circuit boards and before connecting the load connections and signal/control connections, or after connecting the load connections and signal/control connections.
